(19) United States
(12) Patent Application Publication
(10) Pub. No.: US 2026/0280226 A1
(43) Pub. Date: Sep. 17, 2026

(54) LIGHT-EMITTING SEMICONDUCTOR DEVICE, OPTOELECTRONIC COMPONENT, PROJECTION DEVICE AND ELECTRONIC DEVICE

(71) Applicant: ams-OSRAM International GmbH, Regensburg (DE)

(72) Inventors: Bilal SAIF, Regensburg (DE); Joerg Erich SORG, Regensburg (DE)

(73) Assignee: ams-OSRAM International GmbH, Regensburg (DE)

(21) Appl. No.: 18/877,129

(22) PCT Filed: Jun. 22, 2023
(86) PCT No.: PCT/EP2023/067021

§ 371 Date: Dec. 19, 2024

(30) Foreign Application Priority Data
Jun. 23, 2022 (DE) 10 2022 115 658.3

(51) Int. Cl. H01S 5/026; H01S 5/068; H01S 5/227

(52) U.S. Cl. CPC H01S 5/0261; H01S 5/06804; H01S 5/227

(57) ABSTRACT

A light-emitting semiconductor device includes a semiconductor layer stack including a first semiconductor layer of a first conductivity type, an active zone for generating electromagnetic radiation, and a second semiconductor layer of a second conductivity type. The light-emitting semiconductor device further includes a current spreading layer over a surface of the semiconductor layer stack and electrically connected to the first semiconductor layer, and a dielectric layer over the current spreading layer. A metal layer is arranged to face at least a portion of the current spreading layer, wherein the dielectric layer is arranged between the current spreading layer, and the metal layer. The light-emitting semiconductor device further includes a readout circuitry electrically connectable to the metal layer and configured to read out a capacitance between the metal layer and the current spreading layer.

### CROSS-REFERENCE TO RELATED APPLICATIONS

The present application is a national stage entry from International Application No. PCT/EP2023/067021, filed on Jun. 22, 2023, published as International Publication No. WO 2023/247720 A1 on Dec. 28, 2023, and claims priority to German Patent Application No. 10 2022 115 658.3, filed Jun. 23, 2022, the disclosures of all of which are hereby incorporated by reference in their entireties.

### BACKGROUND

Semiconductor laser devices are increasingly used in a variety of applications such as projectors, laser scanners, LIDAR (“light detection and ranging) systems and others. During operation, the temperature of the laser may increase which may result in a shift of the laser wavelength, brightness and stability of laser characteristics. Further, the lifetime of the laser device may be increased by careful temperature monitoring. Therefore, methods for measuring a temperature of a laser device and of further semiconductor devices are being investigated.

It is an object of the present invention to provide an improved light-emitting semiconductor device, an improved optoelectronic component and an improved projector. Further, it is an object to provide an improved method of measuring a temperature light-emitting semiconductor device.

According to embodiments, the above object is achieved by the claimed matter according to the independent claims. Further developments are defined in the dependent claims.

### SUMMARY

A light-emitting semiconductor device comprises a semiconductor layer stack comprising a first semiconductor layer of a first conductivity type, an active zone for generating electromagnetic radiation, and a second semiconductor layer of a second conductivity type. The light-emitting semiconductor device further comprises a current spreading layer over a surface of the semiconductor layer stack and electrically connected to the first semiconductor layer and a dielectric layer over the current spreading layer. A metal layer is arranged to face at least a portion of the current spreading layer, wherein the dielectric layer is arranged between the current spreading layer and the metal layer. The light-emitting semiconductor device further comprises a readout circuitry electrically connectable to the metal layer and configured to read out a capacitance between the metal layer and the current spreading layer.

Due to this configuration, it is possible to determine the temperature of the semiconductor layer stack.

For example, the metal layer may comprise at least two regions that are arranged along a horizontal direction and which are insulated from each other. Accordingly, a spatial distribution of the temperature within the semiconductor layer stack may be determined.

For example, the light-emitting semiconductor device may be implemented as a laser, e.g. an edge-emitting laser or a surface-emitting laser having a horizontal resonator.

According to further embodiments, the light-emitting semiconductor device may be a VCSEL (“vertical cavity surface emitting laser”) or an LED (“light-emitting diode”).

For example, the semiconductor layer stack may be patterned to form a ridge and the current spreading layer may be arranged over a first main surface of the ridge.

The readout circuitry may be configured to determine a temperature of the semiconductor layer stack.

For example, in a case in which the metal layer comprises at least two regions that are arranged along a horizontal direction and which are insulated from each other, the readout circuitry may be configured to determine a spatial distribution of the temperature. For example, determining the spatial distribution may be performed based on a first capacitance between the first portion of the metal layer and the current spreading layer and further based on a second capacitance between the second portion of the metal layer and the current spreading layer.

The light-emitting semiconductor device may further comprise a driver that is configured to supply a current to the current spreading layer. The driver may be connectable to the readout circuit and may be configured to change the current depending on the capacitance read by the readout circuitry. As a result, the injected current may be controlled on the basis of the detected temperature.

According to further embodiments, an optoelectronic component comprises a semiconductor layer stack comprising a first semiconductor layer of a first conductivity type, an active zone for generating electromagnetic radiation, and a second semiconductor layer of a second conductivity type, the semiconductor layer stack being patterned to a plurality of ridges. The optoelectronic component further comprises a plurality of current spreading layers arranged over a first main surface of the ridges and electrically connected to the first semiconductor layer in the respective ridge and a dielectric layer over the current spreading layers. Sections of a metal layer are arranged to face a corresponding one of the current spreading layers, respectively, wherein the dielectric layer is arranged between the current spreading layer and the section of the metal layer. The optoelectronic component further comprises a readout circuitry electrically connectable to the sections of the metal layer and configured to read out a capacitance between the section of the metal layer and the corresponding current spreading layer.

For example, the readout circuitry is further configured to determine a temperature of the corresponding ridge.

The optoelectronic component may further comprise a driver for determining a current to be supplied to a corresponding one of the current spreading layers. The driver may be connectable to the readout circuit and may be configured to determine a current to be supplied on the basis of a temperature detected by the readout circuitry.

Further embodiments are directed to a method for determining a temperature of a light-emitting semiconductor device comprising a semiconductor layer stack comprising a first semiconductor layer of a first conductivity type, an active zone for generating electromagnetic radiation, and a second semiconductor layer of a second conductivity type, a current spreading layer over a surface of the semiconductor layer stack and electrically connected to the first semiconductor layer, a metal layer arranged to face at least a portion of the current spreading layer, and a dielectric layer between the current spreading layer and the metal layer. The method comprises determining a capacitance of a capacitor comprising the metal layer, the dielectric layer and the current spreading layer, and determining a temperature of the semiconductor layer stack on the basis of the determined capacitance.

For example, the metal layer may comprise at least a first and a second region that are arranged along a horizontal direction and which are insulated from each other. The method may further comprise determining a spatial distribution of the temperature of the semiconductor layer stack on the basis of the determined capacitances of a first capacitor comprising the first region of the metal layer and a second capacitor comprising the second region of the metal layer.

A light-emitting semiconductor device according to further embodiments comprises a semiconductor layer stack comprising a first semiconductor layer of a first conductivity type, an active zone for generating electromagnetic radiation, and a second semiconductor layer of a second conductivity type. The light-emitting semiconductor device further comprises a current spreading layer over a surface of the semiconductor layer stack and electrically connected to the first semiconductor layer, a metal layer arranged to face at least a portion of the current spreading layer, and a dielectric layer between the current spreading layer and the metal layer. A material of the dielectric layer is selected from BaTiO₃, PbMgNbO₃, PbTiO₃, PbLaZrTiO₃, BaSrTiO₃, TiO₂, Ta₂O₅, CeO₂, BaZrTiO₃, SiO₂, Si₃N₄, SrTiO₃, PrScO₃, SmScO₃, SrTiO₃, TbScO₃, DyScO₃, and LiNbO₃.

For example, this light-emitting semiconductor device comprises a capacitor that acts as an integrated temperature sensor.

A projection device comprises the light-emitting semiconductor device as described above or the optoelectronic component as described above.

An electronic device comprises the light-emitting semiconductor device as described above, the projection device as described above or the optoelectronic component as described above.

For example, the electronic device may be selected from a computer, a laptop, a smartphone, a laser scanner, and a LIDAR system.

### BRIEF DESCRIPTION OF THE DRAWINGS

The accompanying drawings are included to provide a further understanding of embodiments of the invention and are incorporated in and constitute a part of this specification. The drawings illustrate the embodiments of the present invention and together with the description serve to explain the principles. Other embodiments of the invention and many of the intended advantages will be readily appreciated, as they become better understood by reference to the following detailed description. The elements of the drawings are not necessarily to scale relative to each other. Like reference numbers designate corresponding similar parts.

FIG. 1A shows a cross-sectional view of a light-emitting semiconductor device according to embodiments.

FIG. 1B shows an equivalent circuit diagram of the light-emitting semiconductor device shown in FIG. 1A.

FIGS. 2A and 2B respectively illustrate the relative dielectric characteristics of SiO₂ and BaTiO₃ with temperature.

FIG. 3A shows a cross-sectional view of a light-emitting semiconductor device according to embodiments.

FIG. 3B shows a combined top view of a light-emitting semiconductor device according to embodiments.

FIG. 4A shows a schematic cross-sectional view of a light-emitting semiconductor device according to further embodiments.

FIG. 4B shows an equivalent circuit diagram of the light-emitting semiconductor device shown in FIG. 4A.

FIG. 4C shows a cross-sectional view of an optoelectronic component according to embodiments.

FIG. 4D shows an equivalent circuit diagram of an optoelectronic component according embodiments.

FIG. 5A is an equivalent circuit diagram for illustrating a method of measuring a temperature of a light-emitting semiconductor device.

FIG. 5B shows an equivalent circuit diagram of readout circuitry that is configured to read out the capacitance and determine a temperature as well as of further components of the light-emitting semiconductor device.

FIG. 5C illustrates waveforms for controlling components of a readout circuitry according to an example.

FIG. 6A shows a light-emitting semiconductor device according further embodiments.

FIG. 6B shows a cross-sectional view of a light-emitting semiconductor device according further embodiments.

FIG. 6C shows an example of a top view of the light-emitting semiconductor device illustrated in FIG. 6B.

FIG. 7 summarizes a method according to embodiments.

FIG. 8A illustrates a projection device according to embodiments.

FIG. 8B illustrates an electronic device according to embodiments.

### DETAILED DESCRIPTION

In the following detailed description reference is made to the accompanying drawings, which form a part hereof and in which are illustrated by way of illustration specific embodiments in which the invention may be practiced. In this regard, directional terminology such as “top”, “bottom”, “front”, “back”, “over”, “on”, “above”, “leading”, “trailing” etc. is used with reference to the orientation of the Figures being described. Since components of embodiments of the invention can be positioned in a number of different orientations, the directional terminology is used for purposes of illustration and is in no way limiting. It is to be understood that other embodiments may be utilized and structural or logical changes may be made without departing from the scope defined by the claims.

The description of the embodiments is not limiting. In particular, elements of the embodiments described hereinafter may be combined with elements of different embodiments.

The terms “wafer” or “semiconductor substrate” used in the following description may include any semiconductor-based structure that has a semiconductor surface. Wafer and structure are to be understood to include doped and undoped semiconductors, epitaxial semiconductor layers, e.g. supported by a base semiconductor foundation, and other semiconductor structures. For example, a layer of a first semiconductor material may be grown on a growth substrate of a second semiconductor material. According to further embodiments, the growth substrate may be an insulating substrate such as a sapphire substrate. Depending on the purpose of use, the semiconductor may be based on a direct or an indirect semiconductor material. Examples of semiconductor materials particularly suitable for generation of electromagnetic radiation comprise nitride-compound semiconductors, by which e. g. ultraviolet or blue light or longer wavelength light may be generated, such as GaN, InGaN, AlN, AlGaN, AlGaInN, phosphide-compound semiconductors, by which e.g. green or longer wavelength light may be generated such as GaAsP, AlGaInP, GaP, AlGaP, as well as further semiconductor materials including AlGaAs, SiC, ZnSe, GaAs, ZnO, Ga₂O₃, diamond, hexagonal BN und combinations of these materials. Further examples of semiconductor materials may as well be silicon, silicon-germanium and germanium. The stoichiometric ratio of the compound semiconductor materials may vary. In the context of the present specification, the term “semiconductor” further encompasses organic semiconductor materials.

The term “vertical” as used in this specification intends to describe an orientation which is arranged perpendicular to the first surface of a substrate or semiconductor body.

The terms “lateral” and “horizontal” as used in this specification intends to describe an orientation parallel to a first surface of a substrate or semiconductor body. This can be for instance the die.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

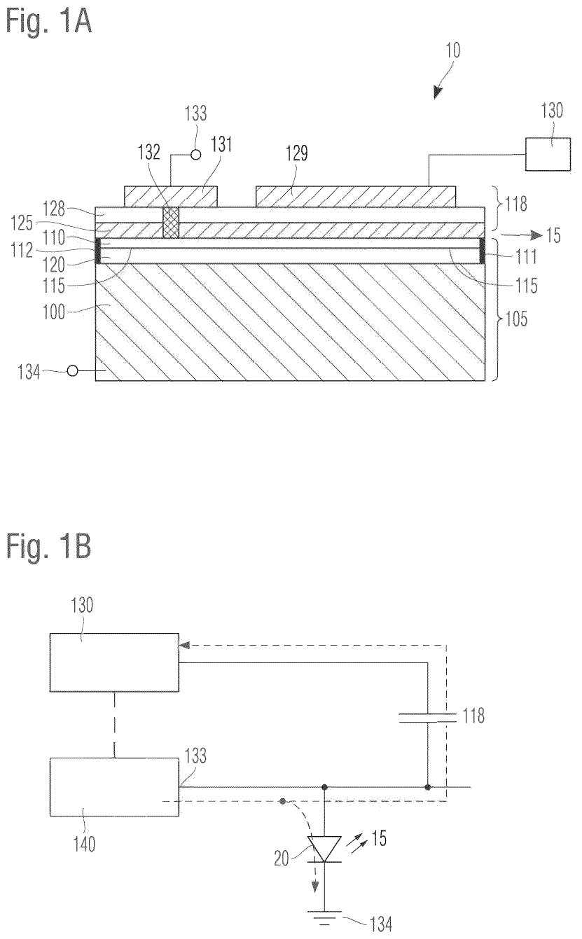

FIG. 1A shows a cross-sectional view of a light-emitting semiconductor device 10 according to embodiments. The light-emitting semiconductor device comprises a semiconductor layer stack 105, comprising a first semiconductor layer 110 of a first conductivity type, e.g. p-type, an active zone 115 for generating electromagnetic radiation, and a second semiconductor layer 120 of a second conductivity type, e.g. n-type.

The active zone 115 may be arranged between the first and second semiconductor layers. The active zone may, for example, comprise a pn junction, a double heterostructure, a single quantum well (SQW) structure or a multi quantum well (MQW) structure for generating radiation. In this process, the term “quantum well structure” has no meaning with regard to the dimensionality of the quantization. Thus, it includes, among other things, quantum wells, quantum wires and quantum dots, as well as any combination of these layers.

For example, the semiconductor layer stack my further comprise a semiconductor substrate 100. For example, the semiconductor substrate 100 may be a growth substrate for growing the semiconductor layer stack 105. Further, the semiconductor layer stack 105 may comprise further layers.

The light-emitting semiconductor device further comprises a current spreading layer 125 which is arranged over a surface of the semiconductor layer stack 105 and which is electrically connected to the first semiconductor layer 110. The current spreading layer 125 may comprise sub-layers (not illustrated in FIG. 1A). The current spreading layer 125 may be arranged in direct contact with the first semiconductor layer 110. For example, the current spreading layer 125 may distribute and inject a current for generating electromagnetic radiation 115. According to embodiments, the light-emitting semiconductor device 10 may implement an edge-emitting laser. The light-emitting semiconductor device may comprise a first and a second resonator mirror 111, 112. A cavity or laser resonator may be formed between the first and second resonator mirrors 111, 112. The first and the second resonator mirrors may be arranged on sidewalls of the semiconductor layer stack 105. For example, a reflectivity of the first resonator mirror 111 may be smaller than the reflectivity of the second resonator mirror 112. The first resonator mirror 111 may implement an outcoupling mirror for coupling out generated electromagnetic radiation 15.

A dielectric layer 128 is arranged over the current spreading layer 125. Moreover, a metal layer 129 is arranged to face at least a portion of the current spreading layer 125. The dielectric layer 128 is arranged between the current spreading layer 125 and the metal layer 129.

For example, a material of the dielectric layer 128 may be selected of the group comprising silicon oxide (SiO₂), silicon nitride (Si₃N₄), aluminum oxide (Al₂O₃), aluminum nitride (AlN) or barium titanate (BaTiO₃). For example, a material having a comparatively large dielectric constant may be selected, e.g. barium titanate. Further, the dielectric constant may be dependent on temperature. For example, at a temperature difference of 30 K, the difference between the dielectric constant may be larger than 0.2. According to further examples, the at a temperature difference of 30 K, the difference between the corresponding dielectric constants may be larger than 10 or larger than 100. Materials especially suitable for the dielectric layer comprise the following materials: PbMgNbO₃, PbTiO₃, PbLaZrTiO₃, BaSrTiO₃, TiO₂, Ta₂O₅, CeO₂, BaZrTiO₃, SrTiO₃, PrSCO₃, SmScO₃, SrTiO₃, TbScO₃, DyScO₃, LiNbO₃.

A capacitor 118 is formed between the metal layer 129 and the current spreading layer 125. By monitoring the capacitance of the capacitor 118, a change of the temperature may be detected. For example, the light-emitting semiconductor device may further comprise a readout circuitry 130 which is electrically connectable to the metal layer and which is configured to read out a capacitance between the metal layer 129 and the current spreading layer 125. For example, the readout circuitry 130 may be electrically connected to the metal layer as illustrated in FIG. 1A.

For example, the light-emitting semiconductor device may further comprise a contact pad 131 that may be connected to the current spreading layer 125 by means of a via contact 132 that extends through the dielectric layer 128. The contact pad 131 may be connected to a suitable terminal 133 for injecting a current into the light-emitting semiconductor device 10. The substrate 100 or a further component, which is electrically connected to the second semiconductor layer 120 may be electrically connected to a second terminal 134.

Various modification of the light-emitting semiconductor device 10 may be made. For example, according to further implementations, the generated electromagnetic radiation 15 may be output over a main surface of the light-emitting semiconductor device 10, e.g. at a position that is not covered with the metal layer 129.

FIG. 1B shows an equivalent circuit diagram of the light-emitting semiconductor device 10 illustrated in FIG. 1A. The light-emitting semiconductor device 10 comprises a light-emitting element 20 e.g., a light-emitting diode or a light-emitting laser diode. The light-emitting element 20 may be electrically connected to a driver 140 that injects a current into the light-emitting element 20.

When a suitable current (indicated by broken lines) is injected, the light-emitting element 20 emits electromagnetic radiation 15. The light-emitting element 20 is further connected to a capacitor 118, which is configured to be connected to a readout circuitry 130.

The light-emitting element 20 may be driven by a driver 140. According to embodiments, the driver 140 may be connected to the readout circuit 130. For example, a current supplied to the light-emitting semiconductor device 10 may be controlled depending on a temperature of the semiconductor layer stack 105. As has been described above, the emission wavelength of the light-emitting semiconductor device 10 may depend on the temperature. Accordingly, the emission wavelength may be further controlled by controlling a current injected. Further, the light-emitting semiconductor device 10 may be switched off or may be operated at a different timing when the temperature of the semiconductor layer stack 105 changes.

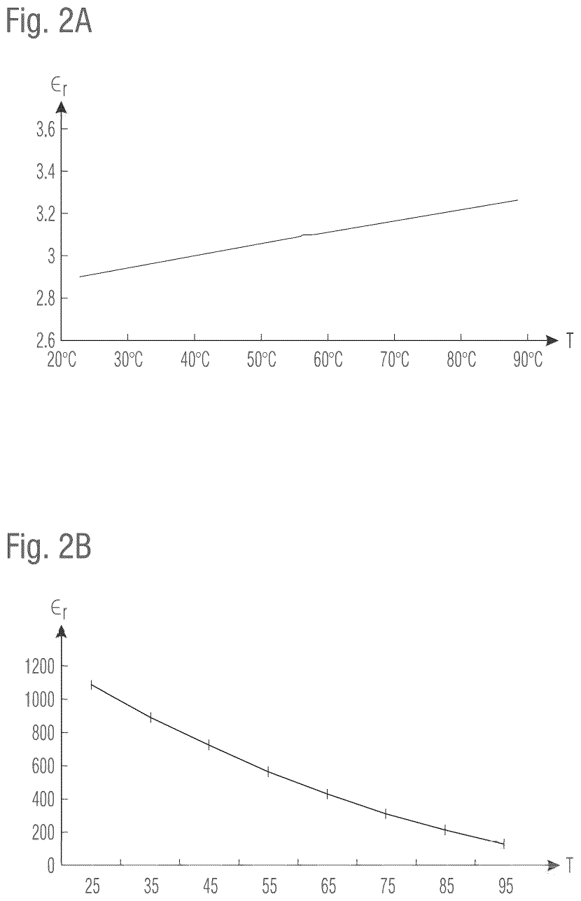

FIG. 2A shows a diagram taken from Fayos-Fernández, José et al. “Temperature-dependent complex permittivity of several electromagnetic susceptors at 2.45 GHz” Delft, AMPERE Newsletter Editor (2018), Issue 95, Mar. 12, 2018. The diagram illustrates the dependence of the relative dielectric constant (Er) or relative permittivity of SiO₂ in dependence of temperature. As is illustrated, the relative dielectric constant in increases with temperature. For example, at a temperature of 30° C., the relative dielectric constant is between 2.9 and 3.0. At a temperature of 80° C., the relative dielectric constant is approximately 3.2.

FIG. 2B shows a diagram taken from Savran, Mehmet Tugrul, “Investigating the effect of temperature on the dielectric constant of ceramic (BaTiO₃)”; IB thesis, Jan. 1, 2014. The diagram shows the relative dielectric constant of BaTiO₃. As is shown, the relative dielectric constant decreases with temperature. For example, at a temperature of 25° C., the relative dielectric constant is between 1000 and 1200. At a temperature of 95° C., the relative dielectric constant is below 200. As can be seen from FIGS. 2A and 2B, by monitoring the capacitance of a capacitor, the temperature change or the absolute temperature of the light-emitting semiconductor device may be determined. In particular, it is possible to measure the temperature without the need of a further temperature sensor. Further, the temperature may be measured while operating the light-emitting semiconductor device. Moreover, the light-emitting semiconductor device comprising a temperature sensor may be implemented in a compact manner.

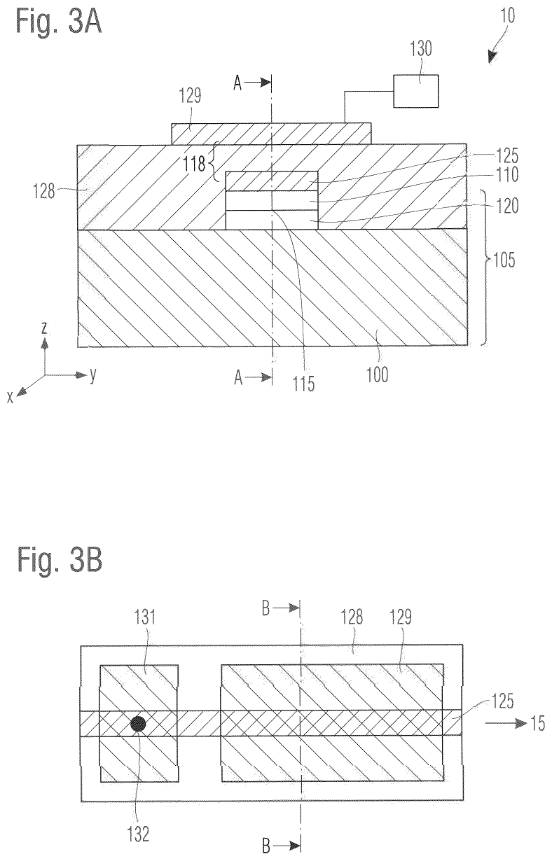

FIG. 3A shows a cross-sectional view of the semiconductor laser device. The position of the cross-sectional view of FIG. 1A is indicated by A-A in FIG. 3A. The cross-sectional view of FIG. 3A is taken perpendicular to an exit surface of the generated electromagnetic radiation 15. The semiconductor layer stack 105 is patterned to form a ridge so that the side walls of the ridge are adjacent to the dielectric layer 128. As is illustrated, in particular, the layer stack comprising the first semiconductor layer 110, the second semiconductor layer 120 and the active zone 115 is patterned to form a ridge. According to further implementations, only the first semiconductor layer 110 may be patterned to form a ridge, and the second semiconductor layer 120 and the active zone 115 may be formed in the portion below the ridge. For example, this portion is not patterned.

The current spreading layer 125 may be arranged over a main surface of the ridge. The metal layer 129 is formed over the current spreading layer 125 and may have a larger width than the current spreading layer 125. The width may be measured in a direction (e.g. y direction) perpendicularly with respect to an extension direction (e.g. x direction) of the ridge. The metal layer 129 faces the current spreading layer 125. The metal layer 129 may be connected or connectable to the readout circuitry 130.

FIG. 3B shows a combined top view of the light-emitting semiconductor device 10 according to embodiments. In particular, the combined top view of FIG. 3B is intended to show components, which are not covered, and, additionally, components, which are covered by further components to illustrate the layout of the semiconductor device. As is illustrated in FIG. 3B, the metal layer 129 is arranged over the current spreading layer 125. The area of the metal layer 129 may be greater than the area of the current spreading layer 125. Further, the contact pad 131 may be connected to the current spreading layer 125 by means of a via contact 132. The area of the metal layer 129 may be larger than the area of the contact pad 131.

According to further embodiments, the metal layer may comprise at least two regions 129₁, 129₂, 129₃, that are arranged along a horizontal direction and which are insulated from each other. For example, the regions 129; of the metal layer may be arranged along the extension direction of the current spreading layer 125 (e.g. x-direction). Due to the presence of these regions, it is possible to improve the resolution of the temperature measurement and to measure a temperature gradient along the extension direction of the current spreading layer 125. For example, the spatial distribution of the temperature may be assessed. Accordingly, it may become possible to predict the temperature behavior of the light-emitting semiconductor device. The readout circuitry 130 may be connectable to the different regions e.g. by means of a switch. For example, the readout circuitry 130 may be sequentially connected to any of the regions 129ᵢ.

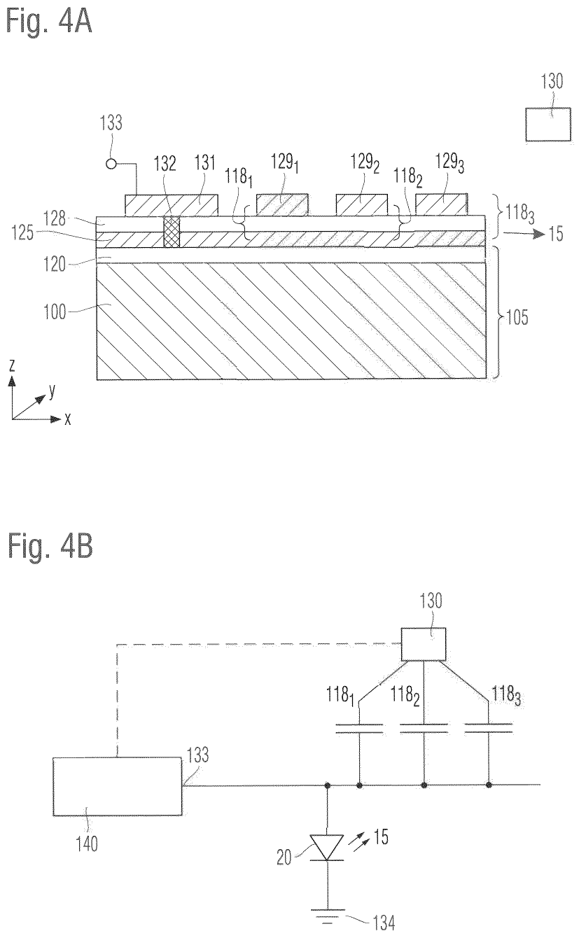

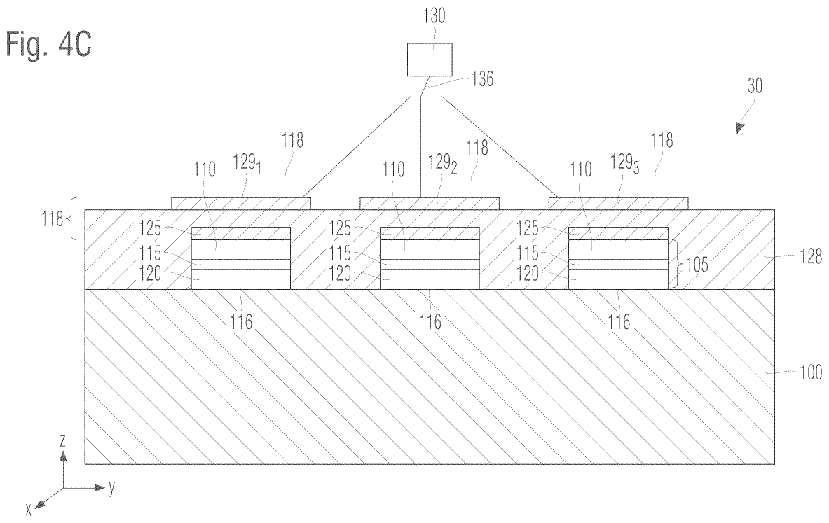

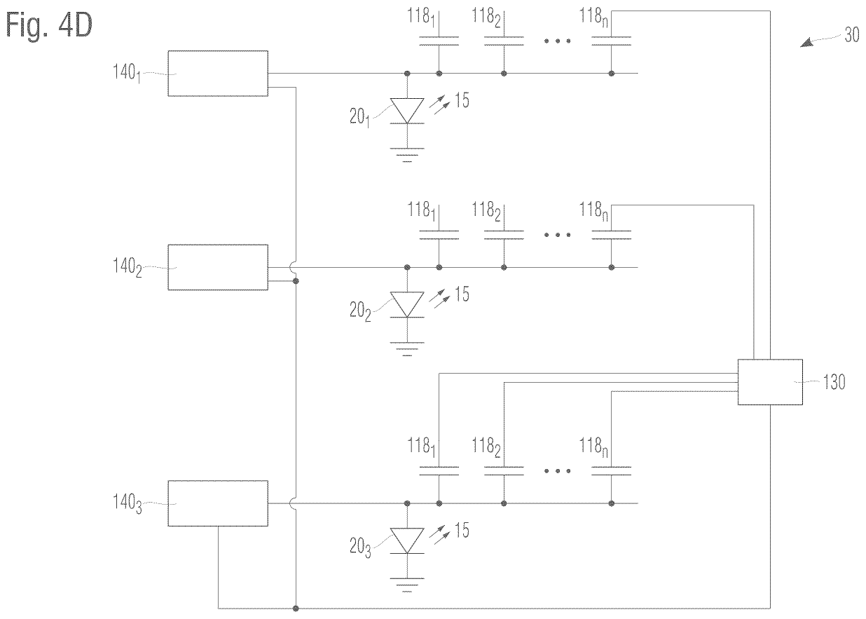

FIG. 4B shows an equivalent circuit diagram of the light-emitting semiconductor device 10 shown in FIG. 4A. As is illustrated, the light-emitting element 20 is connected in parallel with a plurality of capacitors 118₁, 118₂, 118₃. The plurality of capacitors 118₁, 118₂, 118₃, are connected in parallel. Each of the capacitors 118ᵢ may be electrically connected to the readout circuitry 130. The light-emitting element 20 may be driven by a driver 140. According to embodiments, the driver 140 may be connected to the readout circuit 130. For example, a current supplied to the light-emitting semiconductor device 10 may be controlled depending on a temperature of the semiconductor layer stack 105. As has been described above, the emission wavelength of the light-emitting semiconductor device 10 may depend on the temperature. Accordingly, the emission wavelength may be further controlled by controlling a current injected. Further, the light-emitting semiconductor device 10 may be switched off or may be operated at a different timing when the temperature of the semiconductor layer stack 105 changes. According to further implementations, e.g. when due to the specific configuration shown in FIGS. 4A and 4B, the temperature behavior of the semiconductor layer stack 105 may be predicted, it may be possible to perform a more accurate control of the driver 140.

FIG. 4C shows a schematic cross-sectional view of an optoelectronic component 30 according to embodiments. The cross-sectional view of FIG. 4C is taken along the y-direction perpendicular to the extension direction of the current spreading layer 125. The optoelectronic component illustrated in FIG. 4C comprises similar elements as the light-emitting semiconductor device described hereinabove. Differing from embodiments illustrated e.g. in FIG. 3A, the optoelectronic component 30 comprises multiple ridges. To be more specific, the semiconductor layer stack 105 is patterned to form a plurality of ridges 116. The current spreading layer 125 may be arranged over the first main surface of each of the ridges 116. Sections of a metal layer 129₁, 129₂, 129₃ may be arranged over each of the ridges. For example, each of the sections of the metal layer 129 may face a corresponding current spreading layer 125. A dielectric layer 128 is arranged between the current spreading layer 125 and a corresponding one of the metal layer sections 129ᵢ.

The optoelectronic component 30 illustrated in FIG. 4C refers to a multiple ridge system. For example, due to the presence of the multiple ridges, a larger field of view may be illuminated. According to further examples, e.g. using different resonator lengths or different resonator mirrors having a different dependency on an emission wavelength, each of the ridges may be configured to emit a different wavelength. The light-emitting semiconductor device may further comprise a readout circuitry 130, which is electrically connectable to the respective sections of the metal layer 129₁, 129₂, 129₃, e.g. using a switch 136.

FIG. 4D shows an equivalent circuit diagram of the multiple ridge device illustrated in FIG. 4C. For example, elements of a driver 140₁, 140₂, 140₃ may be assigned to each of the different ridges 116 (represented by different light-emitting elements 20₁, 20₂, 20₃ in FIG. 4D), respectively. Accordingly, each of the elements of the driver 140₁, 140₂, 140₃ may drive a corresponding one of the light-emitting elements 20₁, 20₂, and 20₃. The different elements of the driver 140₁, 140₂, 140₃ may be separate or may be combined to a single driver 140. As is further illustrated, the metal layer may be segmented into portions, so that a plurality of capacitors 118₁, . . . 118n are assigned to each of the light-emitting elements 20₁, 20₂, and 20₃, respectively. Each of the light-emitting elements 20₁, 20₂, and 20₃ emits electromagnetic radiation 15 having the same or different wavelengths.

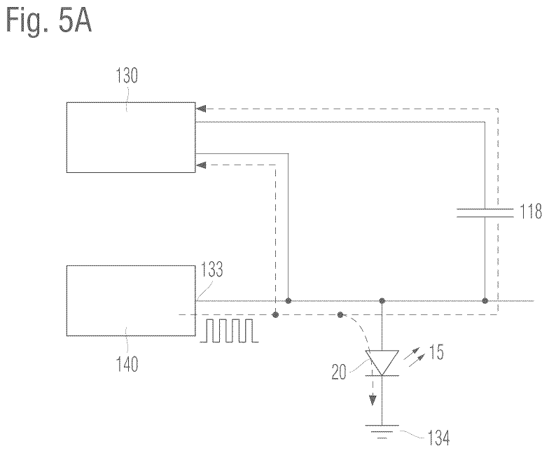

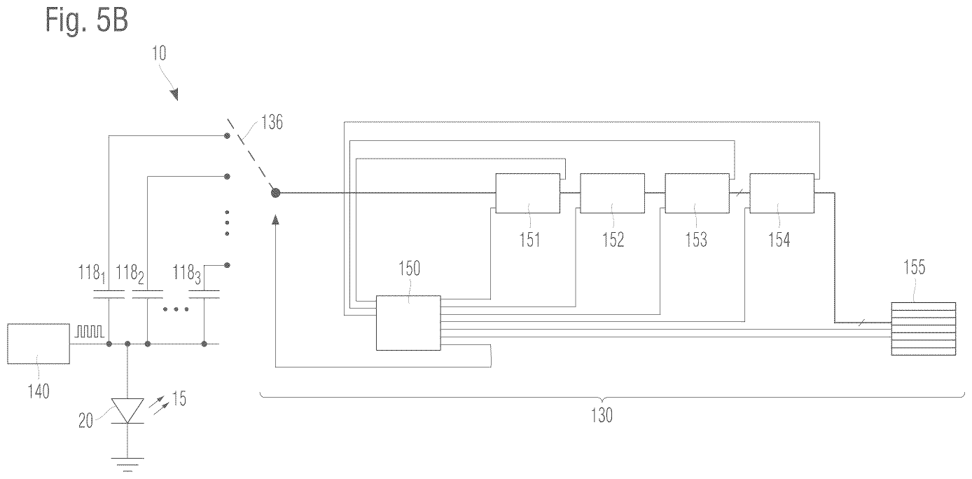

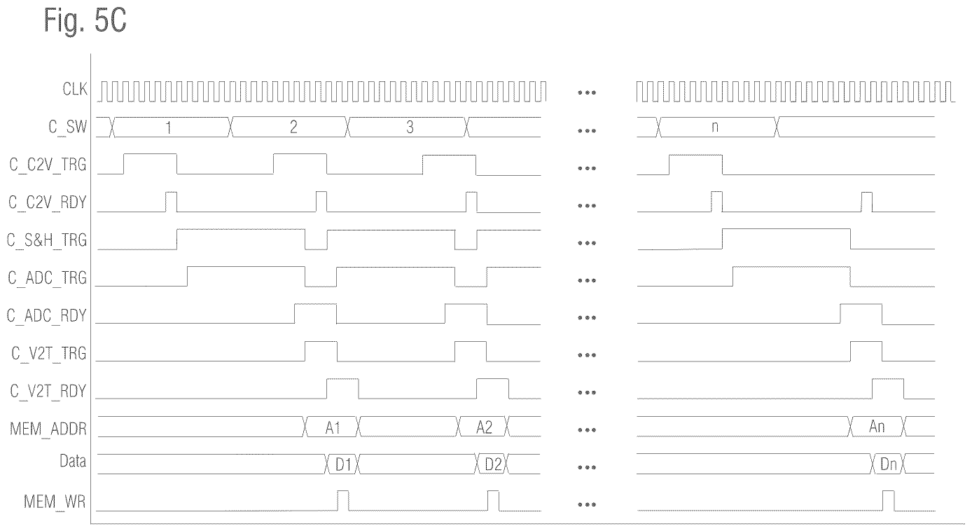

FIG. 5A shows an equivalent circuit diagram for schematically illustrating a passive sensing method for determining the capacitance and, hence, the temperature within the light-emitting semiconductor device. As has been discussed, a driver 140 feeds a corresponding current signal to the light-emitting element 20. For example, the current signal may be a periodically varying signal. Optionally, a reference signal may be branched off and fed to the readout circuitry 130 before the current signal reaches the light-emitting element 20. The current signal is applied to the light-emitting element 20. The capacitor 118 as has been explained above shares a circuit node with the light-emitting element 20. The readout circuitry 130 may comprise a capacitive sensor, which is configured to determine a capacitance of the capacitor 118.

FIG. 5B illustrates the light-emitting semiconductor device 10 comprising the components of the readout circuitry 130 in more detail. The readout circuitry 130 may comprise a central controller 150, which may control the measurement process. The central controller 150 may be implemented in hardware, software or a combination thereof. The respective components of the light-emitting semiconductor device will be explained while referring the waveforms illustrated in FIG. 5C.

For example, the central controller 150 may set the switch 136 to a selected one of the capacitors 118₁, 118₂, 118₃ (e.g. signal C_SW). The central controller 150 may further trigger the capacitance-to-voltage converter 151 (e.g. C_C2V_TRG). For example, the capacitance-to-voltage converter may convert a measured capacitance to a voltage, e.g. using an impedance circuit.

As soon as the capacitance-to-voltage conversion is completed, a corresponding signal (e.g. C_C2V_RDY) is transmitted to the central controller 150. The central controller 150 triggers the sample and hold circuit 152 to store the analogue output of the capacitance-to-voltage converter 151 (e.g. signal C_SH_TRG). After storing the analog voltage, the central controller 150 triggers the analog-two-digital converter 153 (e.g. signal C_ADC_TRG) and sets the switch 136 and the capacitance-to-voltage converter 151 to the next capacitor.

The ADC 153 signals the central controller 150 once the conversion is complete (C_ADC_RDY). At this time, the ADC readout is representing the capacitance in terms of voltage. To extract the temperature information, this voltage will be converted into a temperature. For example, this can be accomplished by a voltage-to-temperature block 154 (C_V2T_TRG). For example, the temperature-to-voltage block 154 may comprise a look-up table for conversion. The voltage-to-temperature block 154 may be implemented with sequential or combinational logic.

After the conversion has been completed, the voltage-to-temperature converter 154 puts the valid data on the data bus and sends a signal to the central controller 150 (C_V2T_RDY). The central controller 150 sends the address to the memory 155 (MEM_ADDR) and triggers the memory write signal (MEM_WR). For example, the data are stored sequentially line by line in the memory 155. After storing the temperature information of capacitor C1, the controller 150 continues with the remaining capacitors. After a while, a temperature map of the lasers is stored in the memory 155. This information may be used for further analysis or correction. For example, as has been explained above, the driver 120 may receive data from the memory 155 to control the current supply to the light-emitting semiconductor device 10 or the optoelectronic component 30.

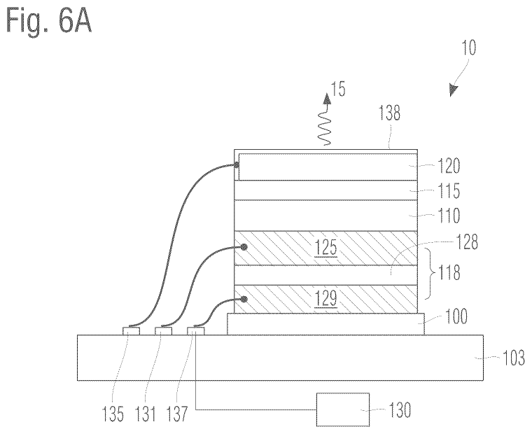

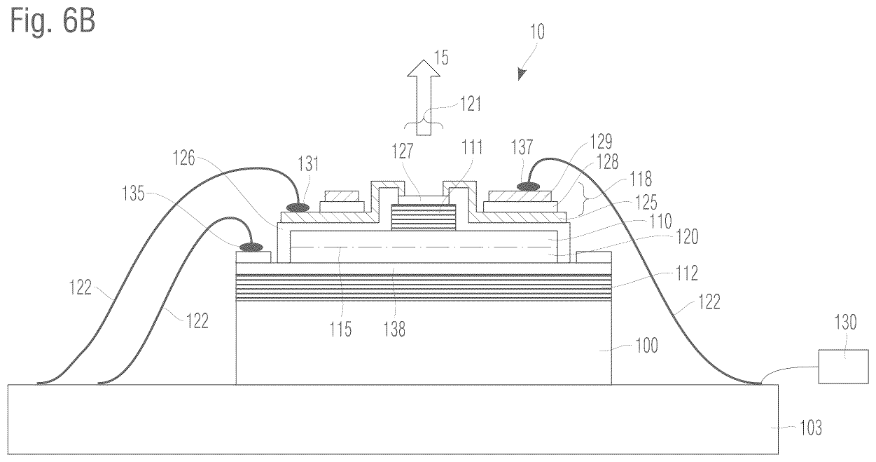

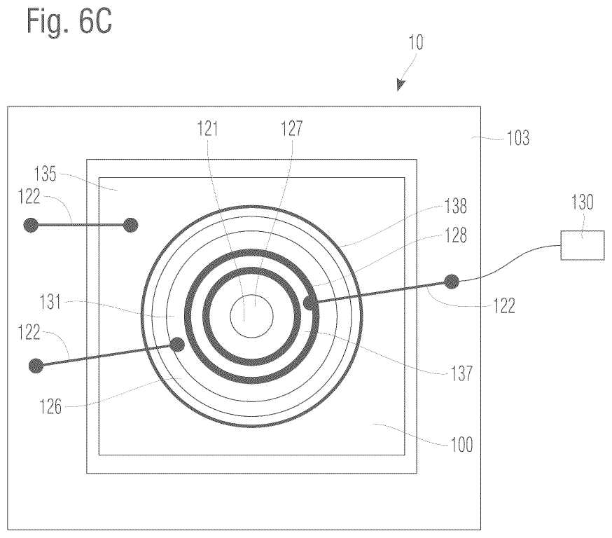

FIG. 6A shows a cross-sectional view of a light-emitting semiconductor device 10 according to further embodiments. The light-emitting semiconductor device 10 may comprise a semiconductor layer stack 105 comprising a first semiconductor layer 110, a second semiconductor layer 120 and an active zone 115 arranged between the first semiconductor layer 110 and the second semiconductor layer 120. A second contact layer 138 may be arranged on a surface of the second semiconductor layer 120. For example, the second contact layer 138 may be made of a transparent material such as ITO (“indium tin oxide”) or may be patterned to a finger-shaped pattern. The second contact layer 135 may be electrically connected to a second contact pad 135. The second contact pad 135 may be arranged on a carrier 103. A current spreading layer 125 may be arranged in contact with the first semiconductor layer 110. A dielectric layer 128 and a metal layer 129 may be arranged on a side of the current spreading layer 125 facing away from the semiconductor layer stack 105. The current spreading layer 125, the dielectric layer 128 and the metal layer 129 form a capacitor 118. The metal layer 129 may be arranged over a substrate 100. The layer stack comprising the semiconductor layer stack 105 and the capacitor 118 may be arranged over the carrier 103. The current spreading layer 125 may be electrically connected to a contact pad 131. The metal layer 129 may be electrically connected to the second capacitor contact pad 137. For example, the second capacitor contact pad 137 may be electrically connected to the readout circuitry 130 which has been explained hereinabove. The contact pad 131 and the second capacitor contact pad 137 may be arranged over the carrier 103. For example, the light-emitting semiconductor device of FIG. 6A may implement a light-emitting diode. Electromagnetic radiation 15 generated by the light-emitting diode may be output via a first main surface of the second semiconductor layer 120, e.g. via the second contact layer. 138.

FIG. 6B shows a cross-sectional view of a light-emitting semiconductor device 10 according to further embodiments. The light-emitting semiconductor device 10 of FIG. 6B is a VCSEL (“vertical cavity surface emitting laser”).

The light-emitting semiconductor device 10 of FIG. 6B comprises a first semiconductor layer 110 of a first conductivity type, a second semiconductor layer 120 of a second conductivity type, and an active zone 115 arranged between the first semiconductor layer 110 and the second semiconductor layer 120. A second contact layer 138 which may be made of a transparent material such as ITO may be arranged on a side of the second semiconductor layer 120 facing away from the first semiconductor layer 110. A second resonator mirror 112 is arranged on a side of the second contact layer 138 facing away from the semiconductor layer stack. A second contact pad 135 is electrically connected to the second contact layer 138. A first resonator mirror 111 may be arranged on a side of the first semiconductor layer 110 facing away from the active zone 115. A first contact layer 127 may be arranged over a surface of the first resonator mirror 111 facing away from the semiconductor layer stack. For example, the first contact layer 127 may be made of a transparent material. A horizontal width of the first contact layer 127 corresponds to an aperture 121 of the light-emitting semiconductor device 10. Electromagnetic radiation 115 emitted by the light-emitting semiconductor device 10 may be output via the aperture 121.

An optical resonator may be formed between the first and the second resonator mirrors 111, 112. By way of example, the first and the second resonator mirrors 111, 112 may be implemented as distributed Bragg reflectors. For example, each of the first and the second resonator mirrors 111, 112 may comprise a plurality of alternating thin layers having different refractive indices, respectively. The thin layers may be formed of a semiconductor or an insulating material. For example, the layers may have a comparatively high refractive index followed by a layer having a comparatively low refractive index. The terms “comparatively high” and “comparatively low” may mean that the comparatively high refractive index is larger than a threshold value. The comparatively low refractive index may be smaller than the threshold value. The threshold value may depend on whether the material of the thin layers is a semiconductor or an insulating material. For example, if the material is a semiconductor material, the threshold value may be 3.1. If the material is an insulating material, the threshold value may be 1.7.

For example, a layer thickness may be λ/4 or an integer multiple of λ/4, wherein λ corresponds to the wavelength of the electromagnetic radiation in the respective material. The first or the second resonator mirror may comprise e.g. 2 to 50 single layers. A typical layer thickness of the single layers may be 30 to 150 nm, e. g. approximately 50 nm. The mirror layer stack may further comprise two or more layers having a thickness larger than about 180 nm, e.g. larger than approximately 200 nm.

When the second resonator mirror 112 is made of semiconductor layers, the second contact layer 138 may be arranged on a side of the second resonator mirror 112 facing away from the semiconductor layer stack. The first contact layer may be electrically connected to a contact pad 131 via a current spreading layer 125. The current spreading layer 125 may be insulated from the first and second semiconductor layers 110, 120 by means of a passivation layer 126. A dielectric layer 128 may be arranged over a portion of the current spreading layer 125. A metal layer 129 may be arranged over the dielectric layer 128. A capacitor 118 may comprise the metal layer 129, the dielectric layer 128 and the current spreading layer 125.

A readout circuitry 130 which has been explained above may be electrically connected to the metal layer 129 via a wiring 122 and a second capacitor contact pad 137. The contact pad 131 which is electrically connected to the current spreading layer 125 and the second contact pad 135 that is electrically connected to the second semiconductor layer may be connected to respective terminals via wirings 122.

FIG. 6C shows a top view of the light-emitting semiconductor device 10 illustrated in FIG. 6B. For example, components of the light-emitting semiconductor device 10 may be patterned to a circular shape.

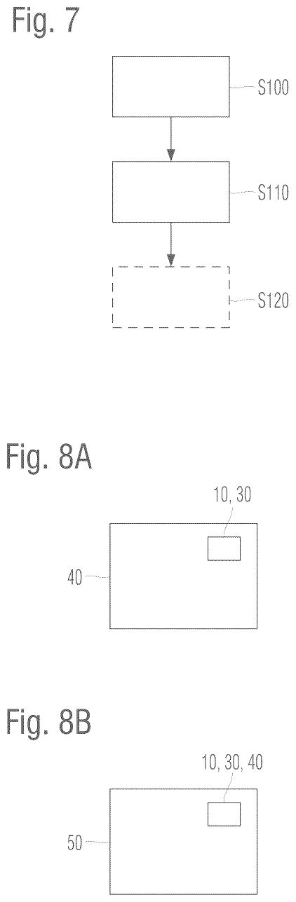

FIG. 7 summarizes a method according to embodiments. A method for determining a temperature of a light-emitting semiconductor device comprising a semiconductor layer stack comprising a first semiconductor layer of a first conductivity type, an active zone for generating electromagnetic radiation, and a second semiconductor layer of a second conductivity type, a current spreading layer over a surface of the semiconductor layer stack and electrically connected to the first semiconductor layer, a metal layer arranged to face at least a portion of the current spreading layer, and a dielectric layer between the current spreading layer and the metal layer, comprises determining (S100) a capacitance of a capacitor comprising the metal layer, the dielectric layer and the current spreading layer. The method further comprises determining (S110) a temperature of the semiconductor layer stack on the basis of the determined capacitance.

The metal layer may comprise at least two regions that are arranged along a horizontal direction and which are insulated from each other. The method may further comprise determining (S120) a spatial distribution of the temperature of the semiconductor layer stack on the basis of the determined capacitances of a first capacitor comprising a first region of the metal layer and a second capacitor comprising a second region of the metal layer.

FIG. 8A is a schematic view of a projection device 40 according to embodiments. A projection device 40 comprises the light-emitting semiconductor device 10 as described above or the optoelectronic component 30 as described above with reference to FIGS. 4C and 4D. The projection device 40 may for example comprise several light-emitting semiconductor devices 10 which emit light of different wavelengths. According to further embodiments, the projection device 40 may comprise an optoelectronic component 30 having multiple ridges each emitting at a different wavelength. The projection device 40 may be configured to generate full color images. For example, in cases in which the light-emitting semiconductor device 10 or the optoelectronic component 30 further comprises a driver 120 that is configured to control a current supply in dependence from the detected temperature in the manner as has been explained above, an improved performance of the projection device 40 may be achieved.

FIG. 8B is a schematic view of an electronic device 50 according to embodiments. The electronic device 50 may comprise the light-emitting semiconductor device 10 as described above or the optoelectronic component 30 as described above with reference to FIGS. 4C and 4D. According to further embodiments, the electronic device 50 may comprise the projection device 40 as illustrated in FIG. 8A. For example, the electronic device 50 may be selected from a computer, a laptop, a smartphone, a laser scanner, a LIDAR system and further laser applications.

While embodiments of the invention have been described above, it is obvious that further embodiments may be implemented. For example, further embodiments may comprise any subcombination of features recited in the claims or any subcombination of elements described in the examples given above. Accordingly, this spirit and scope of the appended claims should not be limited to the description of the embodiments contained herein.

1. A light-emitting semiconductor device comprising:
a semiconductor layer stack comprising a first semiconductor layer of a first conductivity type, an active zone for generating electromagnetic radiation, and a second semiconductor layer of a second conductivity type;
a current spreading layer over a surface of the semiconductor layer stack and electrically connected to the first semiconductor layer;
a dielectric layer over the current spreading layer;
a metal layer arranged to face at least a portion of the current spreading layer, wherein the dielectric layer is arranged between the current spreading layer and the metal layer; and
a readout circuitry electrically connectable to the metal layer and configured to read out a capacitance between the metal layer and the current spreading layer.

2. The light-emitting semiconductor device according to claim 1, wherein the metal layer comprises a first and a second region that are arranged along a horizontal direction and which are insulated from each other.

3. The light-emitting semiconductor device according to claim 1, being implemented as an edge emitting laser.

4. The light-emitting semiconductor device according to claim 1 being implemented as a VCSEL (“vertical cavity surface emitting laser”).

5. The light-emitting semiconductor device according to claim 1 being implemented as an LED (“light-emitting diode”).

6. The light-emitting semiconductor device according to claim 3, wherein the semiconductor layer stack is patterned to form a ridge and the current spreading layer is arranged over a first main surface of the ridge.

7. The light-emitting semiconductor device according to claim 1, wherein the readout circuitry is further configured to determine a temperature of the semiconductor layer stack.

8. The light-emitting semiconductor device according to claim 7, wherein the metal layer comprises at least two regions that are arranged along a horizontal direction and which are insulated from each other, and the readout circuitry is configured to determine a spatial distribution of the temperature based on a first capacitance between the first portion of the metal layer and the current spreading layer and further based on a second capacitance between the second portion of the metal layer and the current spreading layer

9. The light-emitting semiconductor device according to claim 1 further comprising a driver configured to supply a current to the current spreading layer the driver being connectable to the readout circuit and being configured to change the current depending on the capacitance read by the readout circuitry

10. An optoelectronic component comprising:
a semiconductor layer stack comprising a first semiconductor layer of a first conductivity type, an active zone for generating electromagnetic radiation, and a second semiconductor layer of a second conductivity type, the semiconductor layer stack being patterned to a plurality of ridges;
a plurality of current spreading layers arranged over a first main surface of the ridges and electrically connected to the first semiconductor layer in the respective ridge;
a dielectric layer over the current spreading layers;
sections of a metal layer which are arranged to face a corresponding one of the current spreading layers, respectively, wherein the dielectric layer is arranged between the current spreading layer and the section of the metal layer; and
a readout circuitry electrically connectable to the sections of the metal layer and configured to read out a capacitance between the section of the metal layer and the corresponding current spreading layer.

11. The optoelectronic component according to claim 10, wherein the readout circuitry is further configured to determine a temperature of the corresponding ridge.

12. The optoelectronic component according to claim 11, further comprising a driver (120) for determining a current to be supplied to a corresponding one of the current spreading layers, and
the driver being connectable to the readout circuit and being configured to determine a current to be supplied on the basis of a temperature detected by the readout circuitry.

13. A method for determining a temperature of a light-emitting semiconductor device comprising:
a semiconductor layer stack comprising a first semiconductor layer of a first conductivity type, an active zone for generating electromagnetic radiation, and a second semiconductor layer of a second conductivity type;
a current spreading layer over a surface of the semiconductor layer stack and electrically connected to the first semiconductor layer;
a metal layer arranged to face at least a portion of the current spreading layer; and
a dielectric layer between the current spreading layer and the metal layer,
the method comprising:
determining a capacitance of a capacitor comprising the metal layer, the dielectric layer and the current spreading layer, and
determining a temperature of the semiconductor layer stack on the basis of the determined capacitance.

14. The method according to claim 13, wherein the metal layer comprises a first and a second region that are arranged along a horizontal direction and which are insulated from each other and the method further comprises determining a spatial distribution of the temperature of the semiconductor layer stack on the basis of the determined capacitances of a first capacitor comprising the first region of the metal layer and a second capacitor comprising the second region of the metal layer.

15-18. (canceled)
